(19) United States
(12) Patent Application Publication
(10) Pub. No.: US 2024/0395761 A1
(43) Pub. Date: Nov. 28, 2024

(54) METAL CLIP STRUCTURE AND SEMICONDUCTOR PACKAGE INCLUDING THE SAME

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/426,159

(22) Filed: Jan. 29, 2024

(30) Foreign Application Priority Data
May 26, 2023 (KR) 10-2023-0068019

(51) Int. Cl. H01L 23/00; H01L 23/367; H01L 23/498; H01L 25/07

(52) U.S. Cl. CPC H01L 24/37; H01L 23/3677; H01L 23/498; H01L 24/29; H01L 24/32; H01L 24/40; H01L 24/45; H01L 24/48; H01L 24/73; H01L 25/072; H01L 2224/29111; H01L 2224/29139; H01L 2224/29147; H01L 2224/32227; H01L 2224/32238; H01L 2224/37147; H01L 2224/37624; H01L 2224/37639; H01L 2224/37644; H01L 2224/37655; H01L 2224/40229; H01L 2224/404; H01L 2224/45124; H01L 2224/48177; H01L 2224/48178; H01L 2224/73221; H01L 2224/73263; H01L 2224/73265; H01L 2924/1203; H01L 2924/13055; H01L 2924/13091

(57) ABSTRACT

The present invention relates to a metal clip structure and a semiconductor package including the same, and more particularly, to a metal clip structure and a semiconductor package including the same which may be light-weighted, increase bond strength of a conductive wire, and minimize contamination occurring due to a solder material used to bond a semiconductor chip to a metal pad.

### CROSS-REFERENCE TO RELATED PATENT APPLICATION

This application claims the benefit of Korean Patent Application No. 10-2023-0068019,filed on May 26, 2023, in the Korean Intellectual Property Office, the disclosure of which is incorporated herein in its entirety by reference.

### BACKGROUND OF THE INVENTION

### 1. Field of the Invention

The present invention relates to a metal clip structure and a semiconductor package including the same, and more particularly, to a metal clip structure and a semiconductor package including the same which may be light-weighted, increase bond strength of a conductive wire, and minimize contamination occurring due to a solder material used to bond a semiconductor chip to a metal pad.

### 2. Description of the Related Art

In general, a semiconductor package includes a semiconductor chip, a lead frame, and a package housing, wherein the semiconductor chip is bonded to an upper part of a metal pad included in a lead frame and is electrically connected to a lead of a lead frame by using a conductive wire bonded thereto.

Meanwhile, Korean Patent Registration No. 10-1982555 is disclosed as a relating prior art. As illustrated in FIG. 1, a semiconductor package according to the prior art includes a lead frame 200′ including a pad 210′ and a lead terminal 220′, a semiconductor chip 300′ installed on a pad 210′, a clip structure 100′ electrically connecting the semiconductor chip 300′ to the lead terminal 220′, and a bonding wire 600′ electrically connecting the semiconductor chip 300′ to the clip structure 100′.

The clip structure is formed by using a single material including Cu or a Cu alloy material containing 50% or more of Cu for a soldering bond, however, Cu is considerably expensive and heavy compared with other materials.

Also, when a bonding wire is bonded to an upper surface of a clip structure, a soldering material of the clip structure comes up to a wire bonding area so as to interrupt wire bonding. Accordingly, bonding quality may be lowered.

In this regard, there is a demand for the technology that may increase bond strength of a conductive wire and minimize contamination occurring due to a solder material used to bond a semiconductor chip to a metal pad.

### SUMMARY OF THE INVENTION

The present invention provides a metal clip structure and a semiconductor package including the same which may be light-weighted, increase bond strength of a conductive wire, and minimize contamination occurring due to a solder material used to bond a semiconductor chip and a metal pad.

According to an aspect of the present invention, there is provided a metal clip structure including: a main metal clip part which is bent at a regular angle by making a height difference and comprises a lower part at one side thereof electrically bonded to an upper surface of a metal pad or an upper surface of an external terminal and a lower part at the other side thereof electrically bonded to an upper surface of a semiconductor chip; and at least one sub metal layer which is formed of a metal material that is different from that of the main metal clip part, is inserted into at least one insertion groove formed on any one of the upper part at one side and the upper part at the other side of the main metal clip part so as for the top surfaces thereof to be exposed, and is structurally and electrically bonded to the insertion groove, wherein the sub metal layer is bonded and electrically connected to the other adjacent semiconductor chip, the external terminal, or the other adjacent sub metal layer by using conductive wires,
wherein the thickness of the sub metal layer is thinner than the thickness of the main metal clip part and the volume of the sub metal layer is smaller than the volume of the main metal clip part, and wherein the sub metal layer is a metal material containing Al or 50% or more of Al and the main metal clip part is a metal material containing Cu or 50% or more of Cu.

Here, a remaining thickness of the main metal clip part which excludes the depth of the insertion groove may be formed to be greater than the thickness of the sub metal layer.

Also, the main metal clip part may partially or entirely include a plating layer containing 50% or more of Au, Ag, or Ni formed on the surface thereof.

Also, the sub metal layer and the insertion groove may include an intermetallic compound formed by combining a Cu material and an Al material on at least a part of a bonded surface thereof.

According to another aspect of the present invention, there is provided a semiconductor package including: at least one metal pad on which at least one semiconductor chip is installed by using adhesive members interposed therebetween; at least one external terminal electrically connected to the at least one semiconductor chip; a metal clip structure comprising a main metal clip part and at least one sub metal layer, wherein the main metal clip part is bent at a regular angle by making a height difference and comprises a lower part at one side thereof electrically bonded to the upper surface of the metal pad or the upper surface of the external terminal and a lower part at the other side thereof electrically bonded to the upper surface of the semiconductor chip, and wherein the at least one sub metal layer is formed of a metal material that is different from that of the main metal clip part, is inserted into at least one insertion groove formed on any one of the upper part at one side and the upper part at the other side of the main metal clip part so as for the top surfaces thereof to be exposed, and is structurally and electrically bonded to the insertion groove; and a package housing covering the semiconductor chip and a part of the external terminal, wherein the sub metal layer is bonded and electrically connected to the other adjacent semiconductor chip, the external terminal, or the other adjacent sub metal layer by using conductive wires, wherein the thickness of the sub metal layer is thinner than the thickness of the main metal clip part and the volume of the sub metal layer is smaller than the volume of the main metal clip part, and wherein the sub metal layer is a metal material containing Al or 50% or more of Al and the main metal clip part is a metal material containing Cu or 50% or more of Cu.

Here, a remaining thickness of the main metal clip part which excludes the depth of the insertion groove may be formed to be greater than the thickness of the sub metal layer.

Also, the main metal clip part may partially or entirely include a plating layer containing 50% or more of Au, Ag, or Ni formed on the surface thereof.

Also, the sub metal layer and the insertion groove may include an intermetallic compound formed by combining a Cu material and an Al material on at least a part of a bonded surface thereof.

Also, the metal pad may be an insulating substrate comprising at least one insulating layer.

Here, the insulating layer may be formed of Al₂O₃, AlN, or Si₃N₄.

Also, the metal pad may be formed of a metal material containing Cu or 50% or more of Cu.

Also, the at least one external terminal may be spaced apart from the at least one metal pad by a regular distance.

Also, one surface or the other surface of the metal pad may be partially or entirely exposed to the upper surface, the lower surface, or the upper and lower surfaces of the package housing.

Also, the semiconductor chip or the metal clip structure may be electrically or structurally bonded onto the metal pad by using an adhesive member interposed therebetween which is a solder material containing Sn or a sintering material containing Ag or Cu.

Also, at least one first electrical signal line may be further included and electrically connected between the semiconductor chip and the sub metal layer.

Also, at least one second electrical signal line may be further included and electrically connected between the external terminal and the sub metal layer.

Here, the first electrical signal line or the second electrical signal line may be ultrasonic welded and structurally bonded to the sub metal layer.

Here, the first electrical signal line or the second electrical signal line may contain Al or 70% or more of Al.

Also, the thickness of the first electrical signal line or the second electrical signal line may be 0.5 mm through 3.0 mm.

Also, at least one sub metal layer may include at least one metal layer.

Also, the semiconductor package described above may be used in a power conversion device.

Also, the at least one metal pad may include pin-fins structurally bonded thereto.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a semiconductor package structure according to a prior art;

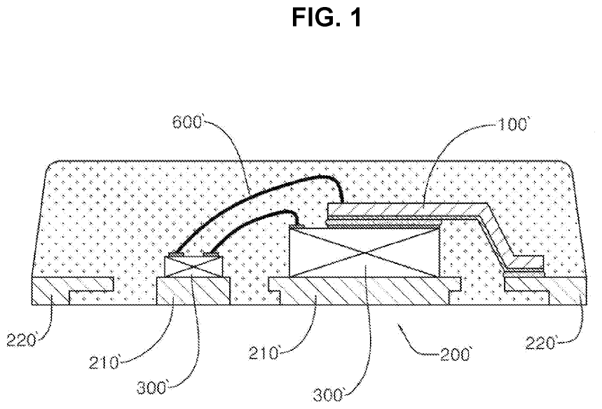

FIGS. 2A, 2B illustrate a metal clip structure according to an embodiment of the present invention;

FIG. 3 illustrates a semiconductor package according to another embodiment of the present invention;

FIG. 4 illustrates another example of the semiconductor package of FIG. 3; and

FIG. 5 illustrates another example of the semiconductor package of FIG. 3.

### DETAILED DESCRIPTION OF THE INVENTION

Hereinafter, embodiments of the present invention will be described in more detail with reference to the accompanying drawings.

A metal clip structure according to an embodiment of the present invention includes a main metal clip part 131 and at least one sub metal layer 132, wherein the main metal clip part 131 is bent at a regular angle by making a height difference and includes the lower part A at one side thereof electrically bonded to the upper surface of a metal pad 110 or the upper surface of an external terminal 120 and the lower part B at the other side thereof electrically bonded to the upper surface of the semiconductor chip 100, and the at least one sub metal layer 132 is formed of a metal material that is different from that of the main metal clip part 131, is inserted into at least one insertion groove 131a formed on the upper part at one side and/or the upper part at the other side of the main metal clip part 131 so as for the top surfaces thereof to be exposed, and is structurally and electrically bonded to the insertion groove 131a. The sub metal layer 132 is bonded and electrically connected to the other adjacent semiconductor chip 100, the external terminal 120, and/or the other adjacent sub metal layer 132 by using conductive wires. A thickness of the sub metal layer 132 is thinner than a thickness of the main metal clip part 131 and the volume of the sub metal layer 132 is smaller than the volume of the main metal clip part 131. Also, the sub metal layer 132 is a metal material containing Al or 50% or more of Al and the main metal clip part 131 is a metal material containing Cu or 50% or more of Cu. Accordingly, weight lightening may be available, bond strength of conductive wires may increase, and contamination occurring due to a solder material used to bond the semiconductor chip 100 to the metal pad 110 may be minimized.

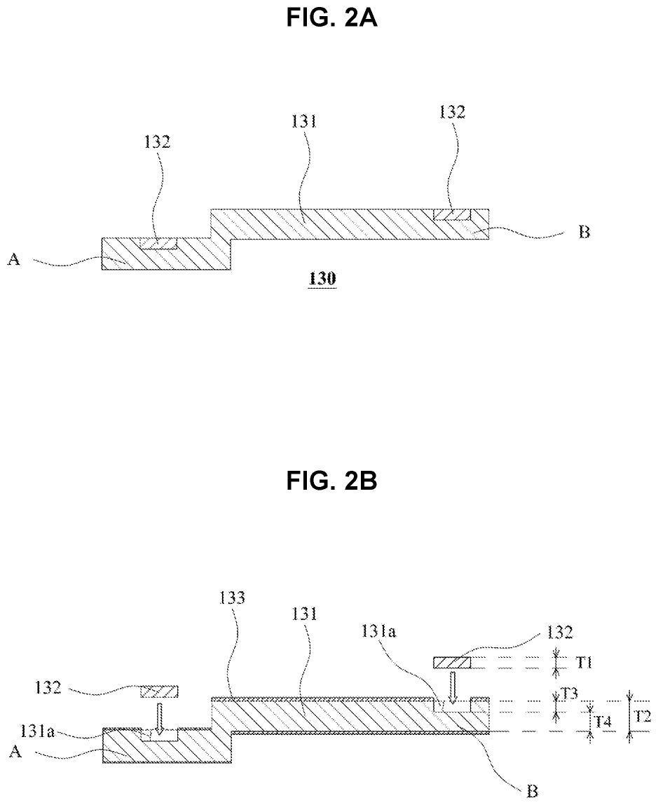

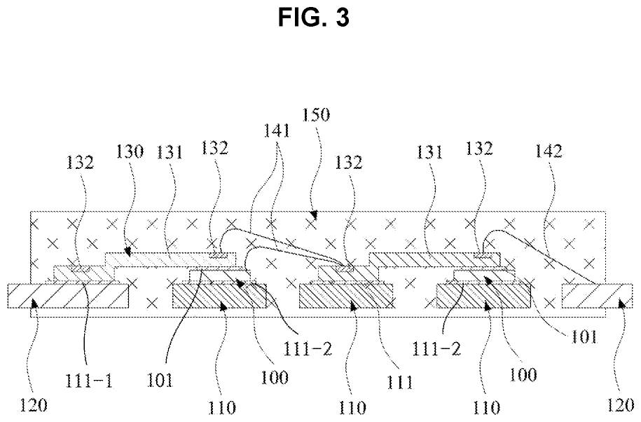

Hereinafter, the metal clip structure as above will be described in more detail with reference to FIGS. 2A, 2B and 3.

First, referring to FIGS. 2A, 2B and 3, the main metal clip part 131 is structurally bent at a regular angle by making a height difference. Here, the lower part A at one side thereof is electrically bonded to the upper surface of the metal pad 110 by using an adhesive member 111 interposed therebetween or the upper surface of the external terminal 120 by using an adhesive member 111-1 interposed therebetween. Also, the lower part B at the other side thereof is electrically bonded to the upper surface of the semiconductor chip 100 by using an adhesive member 101 so that the semiconductor chip 100 and the metal pad 110 are electrically connected to each other.

Next, referring to FIGS. 2A, 2B and 3, at least one sub metal layer 132 is included. The at least one sub metal layer 132 is formed of a metal material that is different from that of the main metal clip part 131, is inserted into at least one insertion groove 131a formed on the upper part at one side and/or the upper part at the other side of the main metal clip part 131 so as for the top surfaces thereof to be exposed, and is structurally and electrically bonded to the insertion grooves 131a.

Here, as illustrated in FIG. 3, the sub metal layer 132 is bonded and electrically connected to the other adjacent semiconductor chip 100, the external terminal 120, and/or the other adjacent sub metal layer 132 of the metal clip structure 130 by using conductive wires 141 and 142. Accordingly, electric signals may be applied through the sub metal layer 132.

Also, as illustrated in FIG. 2B, a thickness T1 of the sub metal layer 132 is thinner than a thickness T2 of the main metal clip part 131 and the volume of the sub metal layer 132 is smaller than the volume of the main metal clip part 131. In addition, the sub metal layer 132 may be a metal material containing Al or 50% or more of Al and the main metal clip part 131 may be a metal material containing Cu or 50% or more of Cu.

In this regard, the metal clip structure according to an embodiment of the present invention may maintain excellent electrical conductivity and may be light-weighted compared with a metal clip structure which is formed of Cu only. Also, when soldering is performed to the main metal clip part 131 by using the adhesive members 101, 111, and 111-1, contamination on the surface of the sub metal layer 132 occurring due to wetting between a solder material came up to a bonding areas of the conductive wires 141 and 142 and the sub metal layer 132 formed of Al material (Al is bad at surface wetting by a solder material) may be minimized. Accordingly, bonding quality of the conductive wires may be improved and thereby, electrical stability may be improved.

Also, a remaining thickness T4 which excludes a thickness T3 of the main metal clip part 131 that corresponds to the depth of the insertion groove 131a, that is, the remaining thickness T4 of the main metal clip part 131 which excludes the depth of the insertion groove 131a is formed to be greater than the thickness T1 of the sub metal layer 132. Accordingly, electrical conductivity may be maintained, weight-lightening may be available, and structural deformation of the main metal clip part 131 by the sub metal layer 132 may be minimized.

In addition, as illustrated in FIG. 2B, a plating layer 133 containing 50% or more of Au, Ag, or Ni which has excellent thermal conductivity is partially or entirely formed on the surface of the main metal clip part 131 so that heat radiation performance may be increased.

Moreover, an intermetallic compound formed by combining a Cu material and an Al material exists on at least a part of a bonded surface of the sub metal layer 132 and the insertion groove 131a so that excellent bonding structure may be formed between the sub metal layer 132 and the insertion groove 131a.

In this regard, the metal clip structure described above is formed in such a way that a metal which enables soldering is separated from a metal which enables wire bonding so that contamination of a wire bonding area occurring due to a solder material may be minimized while soldering is performed.

Meanwhile, a semiconductor package according another embodiment of the present invention includes the semiconductor chip 100, the metal pad 110, the external terminal 120, the metal clip structure 130, a first electrical signal line 141, a second electrical signal 142, and a package housing 150 covering the semiconductor chip 100 and a part of the external terminal 120, wherein the metal clip structure 130 includes the main metal clip part 131 and at least one sub metal layer 132. Here, the main metal clip part 131 is bent at a regular angle by making a height difference and includes the lower part A at one side thereof electrically bonded to the upper surface of a metal pad 110 or the upper surface of an external terminal 120 and the lower part B at the other side thereof electrically bonded to the upper surface of the semiconductor chip 100, and the at least one sub metal layer 132 is formed of a metal material that is different from that of the main metal clip part 131, is inserted into at least one insertion groove 131a formed on the upper part at one side and/or the upper part at the other side of the main metal clip part 131 so as for the top surfaces thereof to be exposed, and is structurally and electrically bonded to the insertion groove 131a.

Here, the sub metal layer 132 is bonded and electrically connected to the other adjacent semiconductor chip 100, the external terminal 120, and/or the other adjacent sub metal layer 132 by using the conductive wires 141 and 142. The thickness of the sub metal layer 132 is thinner than the thickness of the main metal clip part 131 and the volume of the sub metal layer 132 is smaller than the volume of the main metal clip part 131. Also, the sub metal layer 132 is a metal material containing Al or 50% or more of Al and the main metal clip part 131 is a metal material containing Cu or 50% or more of Cu. Accordingly, weight lightening may be available, bond strength of conductive wires may increase, and contamination occurring due to a solder material used to bond the semiconductor chip 100 to the metal pad 110 may be minimized.

Hereinafter, a semiconductor package including the metal clip structure described above will be described in more detail with reference to FIGS. 2A through 5.

First, referring to FIGS. 2A, 2B and 3, at least one metal pad 110 is included and includes at least one semiconductor chip 100 installed on the upper surface thereof by using an adhesive member 111-2 interposed therebetween. Also, the lower part A at one side of the metal clip structure 130 may be electrically or structurally bonded to the metal pad 110 by using the adhesive member 111 interposed therebetween.

Here, referring to FIGS. 2A and 2B, the metal pad 110 is a metal material containing Cu or 50% or more of Cu. In this regard, bond strength with the main metal clip part 131 which is a metal material containing Cu or 50% or more of Cu may be increased.

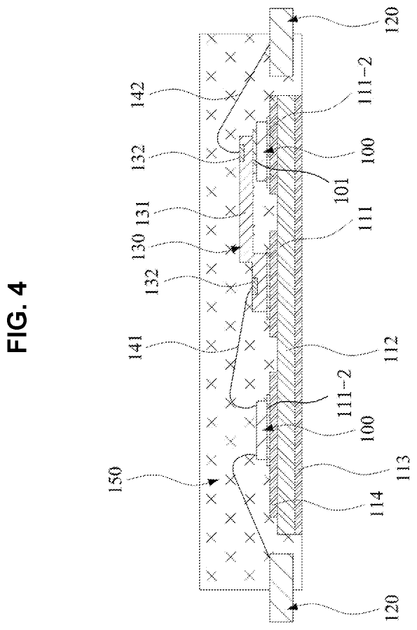

Also, as illustrated in FIG. 4, the metal pad 110 includes at least one insulating layer 112 and may be an insulating substrate where a lower metal layer 113, the insulating layer 112, and an upper metal layer 114 are stacked in order. In addition, the insulating layer 112 may be formed of Al₂O₃, AlN, or Si₃N₄.

Moreover, the semiconductor chip 100 may be a power semiconductor chip of IGBT, MOSFET, or diode which performs power switching or a gate drive IC or a NTC thermistor which performs signal control and thereby, a semiconductor package including the same may be used in power conversion devices.

Next, as illustrated in FIG. 3, at least one external terminal 120 is included and may be electrically connected to the lower part A at one side of the metal clip structure 130 by using the adhesive member 111-1 interposed therebetween or the sub metal layer 132 formed on the upper part of the other side of the metal clip structure 130 by using the conductive wire 142.

Also, as illustrated in FIGS. 2A, 2B and 3, at least one external terminal 120 may be spaced apart from the at least one metal pad 110 by a regular distance and thereby, may be insulated from each other.

Next, the metal clip structure 130 may include the main metal clip part 131 and the sub metal layer 132.

More specifically, referring to FIGS. 2A, 2B and 3, the main metal clip part 131 is structurally bent at a regular angle by making a height difference, wherein the lower part A at one side thereof is electrically bonded to the upper surface of the metal pad 110 by using the adhesive member 111 interposed therebetween or the upper surface of the external terminal 120 by using an adhesive member 111-1 interposed therebetween and the lower part B at the other side thereof is electrically bonded to the upper surface of the semiconductor chip 100 by using an adhesive member 101 so that the semiconductor chip 100, the metal pad 110, and the external terminal 120 are electrically connected to each other.

Next, referring to FIGS. 2A, 2B and 3, at least one sub metal layer 132 is included. The at least one sub metal layer 132 is formed of a metal material that is different from that of the main metal clip part 131, is inserted into at least one insertion groove 131a formed on the upper part at one side and/or the upper part at the other side of the main metal clip part 131 so as for the top surfaces thereof to be exposed, and is structurally and electrically bonded to the insertion grooves 131a.

Here, as illustrated in FIG. 3, the sub metal layer 132 is bonded and electrically connected to the other adjacent semiconductor chip 100, the external terminal 120, and/or the other adjacent sub metal layer 132 of the metal clip structure 130 by using the conductive wires 141 and 142. Accordingly, electric signals may be applied through the sub metal layer 132.

Also, as illustrated in FIG. 2B, the thickness T1 of the sub metal layer 132 is thinner than the thickness T2 of the main metal clip part 131 and the volume of the sub metal layer 132 is smaller than the volume of the main metal clip part 131. In addition, the sub metal layer 132 may be a metal material containing Al or 50% or more of Al and the main metal clip part 131 is a metal material containing Cu or 50% or more of Cu.

In this regard, the metal clip structure according to an embodiment of the present invention may maintain excellent electrical conductivity and may be light-weighted compared with a metal clip structure which is formed of Cu only. Also, when soldering is performed to the main metal clip part 131 by using the adhesive members 101, 111, and 111-1, contamination on the surface of the sub metal layer 132 occurring due to wetting between a solder material came up to a bonding areas of the conductive wires 141 and 142 and the sub metal layer 132 formed of Al material (Al is bad at surface wetting by a solder material) may be minimized. Accordingly, bonding quality of the conductive wires may be improved and thereby, electrical stability may be improved.

Also, the at least one sub metal layer 132 includes at least one dissimilar metal layer so that bond strength and structural strength may be improved.

In addition, the remaining thickness T4 which excludes the thickness T3 of the main metal clip part 131 that corresponds to the depth of the insertion groove 131a, that is, the remaining thickness T4 of the main metal clip part 131 which excludes the depth of the insertion groove 131a is formed to be greater than the thickness T1 of the sub metal layer 132. Accordingly, electrical conductivity may be maintained, weight-lightening may be available, and structural deformation of the main metal clip part 131 by the sub metal layer 132 may be minimized.

Moreover, as illustrated in FIG. 2B, the plating layer 133 containing 50% or more of Au, Ag, or Ni which has excellent thermal conductivity is partially or entirely formed on the surface of the main metal clip part 131 so that heat radiation performance may be increased.

Furthermore, an intermetallic compound formed by combining a Cu material and an Al material exists on at least a part of a bonded surface of the sub metal layer 132 and the insertion groove 131a so that excellent bonding structure may be formed between the sub metal layer 132 and the insertion groove 131a.

Meanwhile, the semiconductor chip 100 or the metal clip structure 130 may be electrically or structurally bonded onto the metal pad 110 by soldering the adhesive member 111 which is a solder material containing Sn or by sintering the adhesive member 111 which is a sintering material containing Ag or Cu.

Next, as illustrated in FIGS. 3 and 4, at least one first electrical signal line 141 may be further included and electrically connected between the semiconductor chip 100 and the sub metal layer 132. Here, the first electrical signal line 141 may be a conductive wire.

Also, at least one second electrical signal line 142 may be further included and electrically connected between the external terminal 120 and the sub metal layer 132. Here, the second electrical signal line 142 may be a conductive wire.

Here, the first electrical signal line 141 or the second electrical signal line 142 may be ultrasonic welded and structurally bonded to the sub metal layer 132.

Also, the first electrical signal line 141 or the second electrical signal line 142 may contain Al or 70% or more of Al and may have a thickness of 0.5 mm through 3.0 mm.

Next, the package housing 150 is formed of EMC, PBT, or PPS and covers the entire semiconductor chip 100 and a part of the external terminal 120 so as to be insulated. Accordingly, the package housing 150 may insulate inner circuits and may be formed for a partial surface of the metal pad 110 to be exposed.

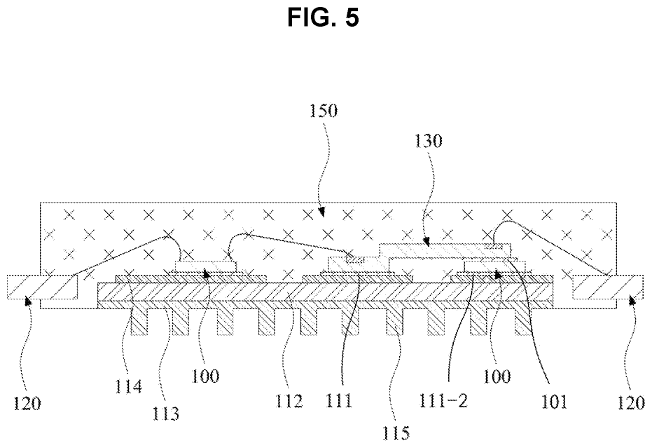

Here, as illustrated in FIGS. 4 and 5, one surface or the other surface of the metal pad 110 is partially or entirely exposed to the upper surface and/or the lower surface of the package housing 150 so that heat generated while being operated may be radiated to the outside.

Also, as illustrated in FIG. 5, pin-fins 115 are structurally bonded to the at least one metal pad 110, for example, the lower metal layer 113 of the insulating substrate, and thereby, may contact refrigerant that circulates a cooling system (not illustrated). Accordingly, thermal stability may be secured.

Therefore, according to the present invention described above, the metal clip structure may be formed in such a way that a metal which enables soldering is separated from a metal which enables wire bonding. Accordingly, the metal clip structure may be light-weighted while maintaining excellent electrical conductivity. Also, a main metal and a sub metal of the metal clip structure are formed using each different material and thereby, contamination on the surface of the sub metal layer occurring due to a solder material may be minimized while soldering is performed. Accordingly, bonding quality of the conductive wires may be improved and thereby, electrical stability may be improved.

According to the present invention, the metal clip structure is formed in such a way that a metal which enables soldering is separated from a metal which enables wire bonding. Accordingly, the metal clip structure may be light-weighted while maintaining excellent electrical conductivity. Also, a main metal and a sub metal of the metal clip structure are formed using each different material and thereby, contamination on the surface of the sub metal layer occurring due to a solder material may be minimized while soldering is performed. Accordingly, bonding quality of the conductive wires may be improved and thereby, electrical stability may be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A metal clip structure comprising:
a main metal clip part which is bent at a regular angle by making a height difference and comprises a lower part at one side thereof electrically bonded to an upper surface of a metal pad or an upper surface of an external terminal and a lower part at the other side thereof electrically bonded to an upper surface of a semiconductor chip; and
at least one sub metal layer which is formed of a metal material that is different from that of the main metal clip part, is inserted into at least one insertion groove formed on any one of the upper part at one side and the upper part at the other side of the main metal clip part so as for the top surfaces thereof to be exposed, and is structurally and electrically bonded to the insertion groove,
wherein the sub metal layer is bonded and electrically connected to the other adjacent semiconductor chip, the external terminal, or the other adjacent sub metal layer by using conductive wires,
wherein the thickness of the sub metal layer is thinner than the thickness of the main metal clip part and the volume of the sub metal layer is smaller than the volume of the main metal clip part, and
wherein the sub metal layer is a metal material containing Al or 50% or more of Al and the main metal clip part is a metal material containing Cu or 50% or more of Cu.

2. The metal clip structure of claim 1, wherein a remaining thickness of the main metal clip part which excludes the depth of the insertion groove is formed to be greater than the thickness of the sub metal layer.

3. The metal clip structure of claim 1, wherein the main metal clip part partially or entirely comprises a plating layer containing 50% or more of Au, Ag, or Ni formed on the surface thereof.

4. The metal clip structure of claim 1, wherein the sub metal layer and the insertion groove comprise an intermetallic compound formed by combining a Cu material and an Al material on at least a part of a bonded surface thereof.

5. A semiconductor package comprising:
at least one metal pad on which at least one semiconductor chip is installed by using adhesive members interposed therebetween;
at least one external terminal electrically connected to the at least one semiconductor chip;
a metal clip structure comprising a main metal clip part and at least one sub metal layer, wherein the main metal clip part is bent at a regular angle by making a height difference and comprises a lower part at one side thereof electrically bonded to the upper surface of the metal pad or the upper surface of the external terminal and a lower part at the other side thereof electrically bonded to the upper surface of the semiconductor chip, and wherein the at least one sub metal layer is formed of a metal material that is different from that of the main metal clip part, is inserted into at least one insertion groove formed on any one of the upper part at one side and the upper part at the other side of the main metal clip part so as for the top surfaces thereof to be exposed, and is structurally and electrically bonded to the insertion groove; and
a package housing covering the semiconductor chip and a part of the external terminal,
wherein the sub metal layer is bonded and electrically connected to the other adjacent semiconductor chip, the external terminal, or the other adjacent sub metal layer by using conductive wires,
wherein the thickness of the sub metal layer is thinner than the thickness of the main metal clip part and the volume of the sub metal layer is smaller than the volume of the main metal clip part, and
wherein the sub metal layer is a metal material containing Al or 50% or more of Al and the main metal clip part is a metal material containing Cu or 50% or more of Cu.

6. The semiconductor package of claim 5, wherein a remaining thickness of the main metal clip part which excludes the depth of the insertion groove is formed to be greater than the thickness of the sub metal layer.

7. The semiconductor package of claim 5, wherein the main metal clip part partially or entirely comprises a plating layer containing 50% or more of Au, Ag, or Ni formed on the surface thereof.

8. The semiconductor package of claim 5, wherein the sub metal layer and the insertion groove comprise an intermetallic compound formed by combining a Cu material and an Al material on at least a part of a bonded surface thereof.

9. The semiconductor package of claim 5, wherein the metal pad is an insulating substrate comprising at least one insulating layer.

10. The semiconductor package of claim 5, wherein the metal pad is formed of a metal material containing Cu or 50% or more of Cu.

11. The semiconductor package of claim 5, wherein the at least one external terminal is spaced apart from the at least one metal pad by a regular distance.

12. The semiconductor package of claim 5, wherein one surface or the other surface of the metal pad is partially or entirely exposed to the upper surface, the lower surface, or the upper and lower surfaces of the package housing.

13. The semiconductor package of claim 5, wherein the semiconductor chip or the metal clip structure is electrically or structurally bonded onto the metal pad by using an adhesive member interposed therebetween which is a solder material containing Sn or a sintering material containing Ag or Cu.

14. The semiconductor package of claim 5, further comprising at least one first electrical signal line electrically connected between the semiconductor chip and the sub metal layer.

15. The semiconductor package of claim 5, further comprising at least one second electrical signal line electrically connected between the semiconductor chip and the sub metal layer.

16. The semiconductor package of claim 14, wherein the first electrical signal line is ultrasonic welded and structurally bonded to the sub metal layer.

17. The semiconductor package of claim 14, wherein the first electrical signal line contains Al or 70% or more of Al.

18. The semiconductor package of claim 5, wherein the at least one sub metal layer comprises at least one metal layer.

19. The semiconductor package of claim 5, wherein the semiconductor package is used in a power conversion device.

20. The semiconductor package of claim 5, wherein the at least one metal pad comprises pin-fins structurally bonded thereto.
